(19) United States
(12) Patent Application Publication
(10) Pub. No.: US 2026/0293443 A1
(43) Pub. Date: Sep. 24, 2026

(54) DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Du CHEN, Beijing (CN); Zhiwen CHU, Beijing (CN); Yuanqi ZHANG, Beijing (CN); Yang ZENG, Beijing (CN); Biao LIU, Beijing (CN); Hongwei MA, Beijing (CN); Yi ZHANG, Beijing (CN); Hai ZHENG, Beijing (CN)

(21) Appl. No.: 19/479,773

(22) PCT Filed: Jan. 14, 2025
(86) PCT No.: PCT/CN2025/072333

§ 371 Date: Oct. 29, 2025

(30) Foreign Application Priority Data
Feb. 28, 2024 (CN) 202410224589.7

(51) Int. Cl. H10K 59/122; H10K 59/131; H10K 59/80

(52) U.S. Cl. CPC H10K 59/122; H10K 59/131; H10K 59/873

(57) ABSTRACT

The present disclosure provides a display panel and a display apparatus. The display panel includes a base substrate, and a planarization layer, a light-emitting layer, and at least one isolation pillar, the light-emitting layer extends from the display region to the second transition region, and is disconnected at a position of each isolation pillar; an isolation pillar surrounding the opening region and closest to the display region is a first isolation pillar, and a first groove in the base substrate is defined between the first isolation pillar and the planarization layer; and the planarization layer includes a flat region and an inclined region, the planarization layer includes a first surface away from the base substrate, a tangent plane at any point on the first surface in the inclined region and a second surface of the base substrate close to the planarization layer form a dihedral angle α therebetween.

### TECHNICAL FIELD

The present disclosure relates to the field of display technology, in particular to a display panel and a display apparatus.

### BACKGROUND

In a related organic light-emitting diode (OLED) display panel, an opening (hole) is usually formed in a screen to accommodate devices such as a camera and a sensor, and the like, but the opening formed in the screen easily exposes layers of the OLED, and therefore, it is necessarily to provide an isolation pillar to block a path through which water and oxygen invade in a light-emitting layer (or electro-luminescence, EL) so as to avoid defects such as growing dark spots (GDS) in a display region (i.e., an active area, AA).

However, as the demands of users on a boundary specification of the AA Hole (the opening in the active area) gradually become strict, a space left for the encapsulation of the isolation pillar in the AA Hole is smaller and smaller. Due to the fluctuation of exposure and development processes of a pixel defining layer, residual glue is easy to remain in an undercut structure of the isolation pillar, so that the blocking of the EL material fails, and a new path through which the water and oxygen invade is formed, which finally causes defects such as GDS and the like.

### SUMMARY

The present disclosure is directed to solving at least one of the technical problems in the related art and provides a display panel and a display apparatus.

In a first aspect, the technical solution adopted for solving the technical problems of the present disclosure is a display panel, including a display region, a first transition region, a second transition region, and an opening region, wherein the second transition region surrounds the opening region and is located between the first transition region and the opening region, the first transition region surrounds the second transition region and is located between the display region and the first transition region, the display panel includes a base substrate, a planarization layer on the base substrate, a light-emitting layer on a side of the planarization layer away from the base substrate, and at least one isolation pillar on the base substrate, the planarization layer extends from the display region to the first transition region, the light-emitting layer extends from the display region to the second transition region, and is disconnected at a position of each isolation pillar, and the at least one isolation pillar is located in the second transition region;

An isolation pillar surrounding the opening region and closest to the display region is a first isolation pillar, and a first groove in the base substrate is defined between the first isolation pillar and the planarization layer; and

The planarization layer includes a flat region and an inclined region, the planarization layer includes a first surface away from the base substrate, a tangent plane at any point on the first surface in the inclined region and a second surface of the base substrate close to the planarization layer form a dihedral angle α therebetween, and a width of the first groove satisfies a formula: W=α×k, where W denotes the width of the first groove, and k represents a coefficient, k∈[0.48, 0.65].

In some embodiments, the planarization layer includes a first planarization sub-layer, a second planarization sub-layer, and a third planarization sub-layer, which are sequentially arranged in a direction away from the base substrate; and

The second planarization sub-layer at least wraps a boundary portion of the first planarization sub-layer close to the first isolation pillar, and the third planarization sub-layer at least wraps a boundary portion of the second planarization sub-layer close to the first isolation pillar.

In some embodiments, the dihedral angle α between the tangent plane and the second surface is between 30° and 40°.

In some embodiments, the planarization layer includes a first planarization sub-layer, a second planarization sub-layer, and a third planarization sub-layer, which are sequentially arranged in a direction away from the base substrate;

A part, located in the inclined region and not covered by the third planarization sub-layer, of the surface of the second planarization sub-layer away from the base substrate is continuous with a part of a surface of the third planarization sub-layer located in the inclined region to form the first surface together with the surface of the third planarization sub-layer located in the flat region.

In some embodiments, an outline edge of an orthographic projection of the third planarization sub-layer on the base substrate is farther from the second transition region than an outline edge of an orthographic projection of the first planarization sub-layer on the base substrate.

In some embodiments, the dihedral angle α between the tangent plane and the second surface is between 22° and 30°.

In some embodiments, the planarization layer includes a first planarization sub-layer, a second planarization sub-layer, and a third planarization sub-layer, which are sequentially arranged in a direction away from the base substrate;

The second planarization sub-layer covers a part of a surface of the first planarization sub-layer located in the inclined region, and the third planarization sub-layer covers a part of a surface of the second planarization sub-layer located in the inclined region; and

A part, located in the inclined region and not covered by the second planarization sub-layer, of the surface of the first planarization sub-layer away from the base substrate is continuous with a part of the surface of the second planarization sub-layer located in the inclined region; and a part, located in the inclined region and not covered by the third planarization sub-layer, of the surface of the second planarization sub-layer away from the base substrate is continuous with a part of the surface of the third planarization sub-layer located in the inclined region to form the first surface together with the surface of the third planarization sub-layer located in the flat region.

In some embodiments, the dihedral angle α between the tangent plane and the second surface is between 18° and 22°.

In some embodiments, the display panel further includes a metal line on a side of the planarization layer close to the base substrate; and

An orthographic projection of the metal line on the base substrate covers an orthographic projection of the corresponding isolation pillar on the base substrate.

In some embodiments, the display panel further includes an interlayer insulating layer located between the at least one isolation pillar and the metal line, and the interlayer insulating layer includes a flat portion and a protruding portion opposite to the metal line; and

The at least one isolation pillar is located on a surface of the protruding portion away from the base substrate.

In some embodiments, each isolation pillar includes a first conductive portion, a second conductive portion, and a third conductive portion, which are sequentially arranged in a direction away from the base substrate; and the first conductive portion and the third conductive portion both protrude from the second conductive portion.

In some embodiments, a difference between a width of the protruding portion and a width of the first conductive portion is greater than 2.9 um.

In some embodiments, a ratio of a width of the first conductive portion to a width of the metal line is between 0.4 and 0.6.

In some embodiments, the display panel includes a first insulating layer, a first gate line, a second insulating layer, a second gate line, an interlayer insulating layer, a first signal line, a first planarization sub-layer, a second signal line, a second planarization sub-layer, a third signal line, and a third planarization sub-layer, which are sequentially arranged in the direction away from the base substrate;

The metal line includes a first metal line and a second metal line, the first metal line and the first gate line are arranged in the same layer, and the second metal line and the second gate line are arranged in the same layer; and

The first isolation pillar is located in the same layer as one of the first signal line, the second signal line and the third signal line.

In some embodiments, the second metal line includes a third surface away from the base substrate, and a difference between a width of the third surface and a width of the first conductive portion is greater than 2.9 um.

In a second aspect, the embodiment of the present disclosure further provides a display apparatus, including the display panel according to any one of the embodiments of the first aspect.

### BRIEF DESCRIPTION OF DRAWINGS

FIG. 1 is a schematic diagram of residual glue filled in an undercut structure in the related art;

FIG. 2 is a schematic diagram of a path through which water and oxygen invade in the structure in FIG. 1;

FIG. 3 is a top view of a display panel according to an embodiment of the present disclosure;

FIG. 4 is a cross-sectional view of the structure in FIG. 3 taken along a line A-A′;

FIG. 5 is another cross-sectional view of the structure in FIG. 3 taken along a line A-A′;

FIG. 6 is a further cross-sectional view of the structure in FIG. 3 taken along a line A-A′;

FIG. 7 is a schematic diagram of collapsing of an undercut structure in the related art; and

FIG. 8 is an enlarged view of an isolation pillar according to an embodiment of the present disclosure.

### DETAIL DESCRIPTION OF EMBODIMENTS

To make the objects, technical solutions and advantages of the embodiments of the present disclosure more apparent, the technical solutions of the embodiments of the present disclosure will be clearly and completely described below with reference to the drawings of the embodiments of the present disclosure. It is to be understood that the described embodiments are only a few, not all of, embodiments of the present disclosure. Components of the embodiments of the present disclosure, as generally described and illustrated in the drawings herein, could be arranged and designed in a wide variety of different configurations. Thus, the following detailed description of the embodiments of the present disclosure in the drawings is not intended to limit the protective scope of the present disclosure, but is merely representative of selected embodiments of the present disclosure. All other embodiments, which can be derived by a person skilled in the art from the embodiments of the present disclosure without any creative effort, are within the protective scope of the present disclosure.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term of “comprising”, “including”, or the like, means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

The phrase “a plurality of” or “multiple” or “several” used in this disclosure means two or more. The phrase “and/or” describes the association relationship of the associated objects, indicating that there may be three relationships; for example, A and/or B, which may indicate the following three cases: A exists alone, A and B both exist, and B exists alone. The character “/” generally indicates that the preceding and following associated objects are in an “or” relationship.

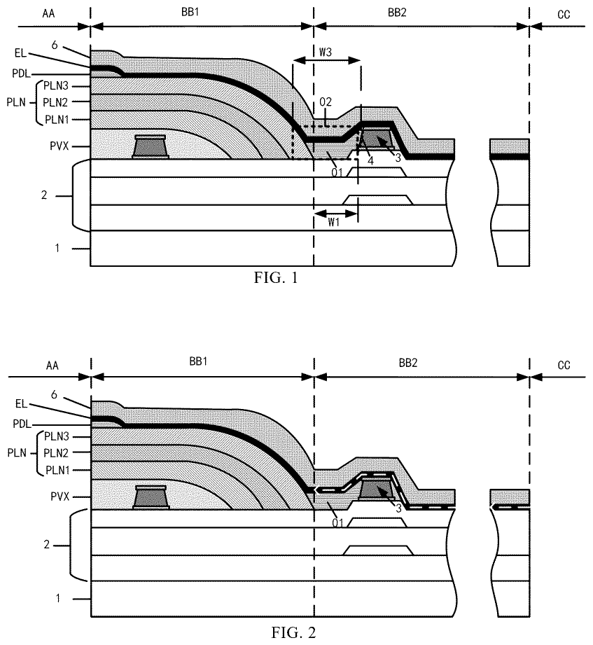

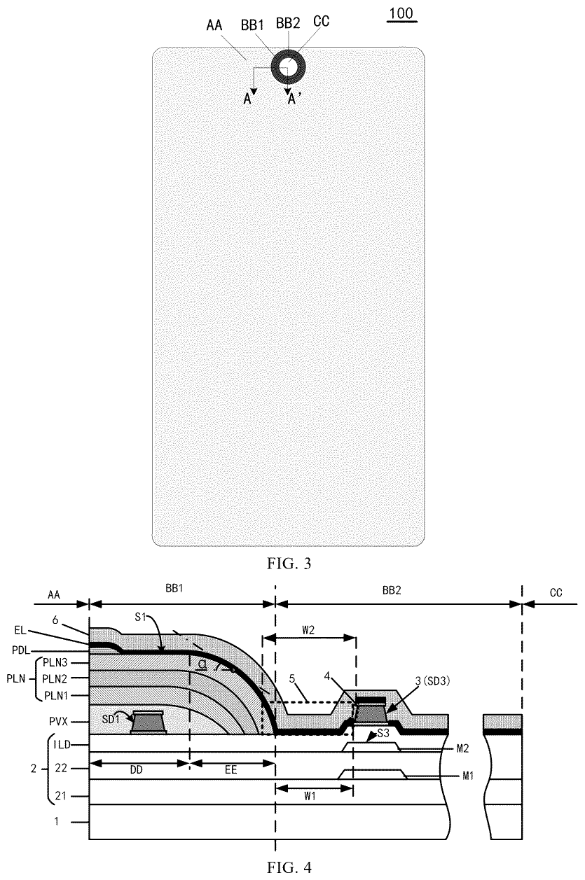

FIG. 1 is a schematic diagram of residual glue filled in an undercut structure in the related art. FIG. 2 is a schematic diagram of a path through which water and oxygen invade (i.e., the water oxygen invading path) in the structure in FIG. 1. FIG. 3 is a top view of a display panel according to an embodiment of the present disclosure. FIG. 4 is a cross-sectional view of the structure in FIG. 3 taken along a line A-A′.

As shown in FIGS. 3 and 4, the display panel 100 provided by the embodiment of the present disclosure has a display region AA, a first transition region BB1, a second transition region BB2, and an opening region CC, wherein the second transition region BB2 surrounds the opening region CC and is located between the first transition region BB1 and the opening region CC; and the first transition region BB1 surrounds the second transition region BB2 and is located between the display region AA and the first transition region BB1. The opening region CC is provided with an opening for installing a device such as a camera, or a sensor, or the like. The display region AA is provided with a plurality of light-emitting devices, and light-emitting layers EL of the light-emitting devices are generally formed as the entire surface in the display region AA, so that during an encapsulation process by using an encapsulation layer 6, a region located in the vicinity of the opening tends to be difficult to be encapsulated, or even if it is encapsulated, it is difficult to ensure the encapsulation effect of the region. Therefore, isolation pillars are provided in the second transition region BB2 to prevent impurities such as water and oxygen from entering the display region AA along the light-emitting layer EL formed as the entire surface from the opening region CC, which may cause defects such as GDS.

As shown in FIGS. 3 and 4, the display panel 100 includes a base substrate 1, an intermediate structure layer 2 disposed on the base substrate 1, a planarization layer PLN disposed on a side of the intermediate structure layer 2 away from the base substrate 1, a pixel defining layer PDL and a light-emitting layer EL disposed on a side of the planarization layer PLN away from the base substrate 1, and at least one isolation pillar disposed on the base substrate 1.

The intermediate structure layer 2 includes a pixel driving circuit, first electrodes of the light-emitting devices, and signal lines of components (e.g., a camera and a sensor located in the opening region). The planarization layer PLN extends from the display region AA to the first transition region BB1 for realizing the planarization of the underneath encapsulated structure. The pixel defining layer PDL has a pixel opening in which a part of the light-emitting layer EL is located. The light-emitting layer EL extends from the display region AA to the second transition region BB2, and is disconnected at a position of each isolation pillar. At least one isolation pillar is located in the second transition region BB2.

As shown in FIG. 4, the isolation pillar surrounding the opening region CC and closest to the display region AA is a first isolation pillar 3, and a first groove 5 is defined between the first isolation pillar 3 and the planarization layer PLN and disposed in the base substrate 1.

However, due to the fluctuation of exposure and development processes of the pixel defining layer PDL, a residual glue 01 may be formed in a second groove 02, as shown in FIG. 1, and further the residual glue 01 is filled in an undercut structure 4 of the first isolation pillar 3. Since the residual glue 01 is filled in the undercut structure 4 of the first isolation pillar 3, on one hand, a path, through which water and oxygen invade, formed by a material of the light-emitting layer EL cannot be cut off by the isolation pillar, and on the other hand, a new path through which water and oxygen invade may be formed to damage the encapsulation structure, as shown in FIG. 2. The narrower the second groove 02 is, the more difficult the washing process of the residual glue 01 formed in the second groove 02 is. Conversely, the wider the second groove 02 is, the easier the washing process of the residual glue 01 in the second groove 02 is.

In this regard, in the present disclosure, the second groove 02 is optimized to form the first groove 5. As shown in FIG. 4, the first groove 5 is defined by the first isolation pillar 3 and the planarization layer PLN, so that the planarization layer PLN may be optimized to form the first groove 5. For example, a width W1 of the first groove 5 may be increased by reducing an area of the planarization layer PLN in a direction from the second transition region BB2 to the display region AA such that an edge of the planarization layer PLN is further away from the second transition region BB2. The width W1 of the first groove 5 may be understood as: a shortest distance from an outline boundary of an orthographic projection of the planarization layer PLN on the base substrate 1 to an outline boundary of an orthographic projection of the first isolation pillar 3 on the base substrate 1. Alternatively, a thickness of the planarization layer PLN may be reduced, so that a slope of a portion of the planarization layer PLN in an inclined region EE is gradually reduced, to increase an opening width W2 of the first groove 5. The opening width W2 of the first groove 5 may be understood as: a shortest distance from an edge of a surface, of the first isolation pillar 3 away from the base substrate 1, close to the display region AA horizontally extending to contact with the planarization layer PLN. The opening width W2 of the first groove 5 away from base substrate 1 is related to a height of the first isolation pillar 3 and the slope of the portion of the planarization layer PLN in the inclined region EE. Under the condition that the height of the first isolation pillar 3 is constant, the greater α is, the steeper the slope of the portion of the planarization layer PLN in the inclined region EE is, the narrower an opening of the first groove 5 is, and the more difficult the residual glue 01 in the first groove 5 is to remove during the preparation process. Conversely, the smaller the α is, the gentler the slope of the portion of the planarization layer PLN in the inclined region EE is, and the wider the opening of the first groove 5 is, the easier the residual glue 01 in the first groove 5 is to remove or clean. However, no matter which way of optimizing the planarization layer PLN is adopted, the formed planarization layer PLN includes a flat region DD and the inclined region EE, and the planarization layer includes a first surface S1 away from the base substrate; a dihedral angle α is formed between a tangent plane at any point on the first surface S1 in the inclined region EE and a second surface of the base substrate 1 close to the planarization layer PLN (for convenience of description, a is shown in FIG. 4 as an acute angle between the tangent plane and a reference plane parallel to the second surface). The width W1 of the first groove 5 satisfies the formula: W=α×k, where W denotes the width W1 of the first groove 5, and k represents a coefficient, k∈[0.48, 0.65].

According to the embodiment of the present disclosure, by optimizing the structure of the planarization layer PLN, the width W1 and/or the opening width W2 of the first groove 5 is increased, so that the residual glue 01 in the first groove 5 is easily cleaned out in the preparation process, that is, the phenomenon that the residual glue 01 is filled in the undercut structure 4 due to the fluctuation of exposure processes of the pixel defining layer PDL is eliminated, thereby ensuring that the first isolation pillar 3 can completely cut off the light-emitting layer EL, further blocking the water oxygen invading path, and avoiding the GDS and other defects. The light-emitting layer EL in the present disclosure is disconnected at the position of each of the isolation pillars.

It should be noted that k is limited by a magnitude of α, and α is negatively correlated with k, that is, the greater a is, the smaller k is; conversely, the greater a is, the greater k is, so that the width W1 of the first groove 5 is not too large to affect the layout of second isolation pillars (other isolation pillars except for the first isolation pillar 3) in the second transition region BB2. Therefore, in the present disclosure, k may be set according to practical application conditions and experience with k∈[0.48, 0.65].

In some embodiments, in addition to optimizing the planarization layer PLN described above, the width W1 of the first groove 5 may alternatively be increased by reducing the width of the first isolation pillar 3 such that the edge of the first isolation pillar 3 close to the display region AA is farther away from the display region AA.

In some embodiments, as shown in FIG. 4, the width W1 of the first groove 5 may be greater than 13 um.

As can be seen from the above analysis, by optimizing the structure of the planarization layer PLN, both the opening width W2 and the width W1 of the first groove 5 can be increased, thereby increasing the probability of cleaning out the residual glue 01 in the first groove 5, and ensuring that the light-emitting layer EL can be completely cut off by the isolation pillar. Various embodiments for optimizing the planarization layer PLN are described in detail below.

In some embodiments, as shown in FIG. 4, the planarization layer PLN includes a first planarization sub-layer PLN1, a second planarization sub-layer PLN2, and a third planarization sub-layer PLN3, which are sequentially arranged in a direction away from the base substrate 1. Optionally, the second planarization sub-layer PLN2 wraps at least a boundary portion of the first planarization sub-layer PLN1 close to the first isolation pillar 3. For example, the second planarization sub-layer PLN2 wraps at least a surface of the first planarization sub-layer PLN1 in the inclined region EE. The third planarization sub-layer PLN3 wraps at least a boundary portion of the second planarization sub-layer PLN2 close to the first isolation pillar 3. For example, the third planarization sub-layer PLN2 wraps at least a surface of the second planarization sub-layer PLN1 in the inclined region EE. End surfaces of the first planarization sub-layer PLN1, the second planarization sub-layer PLN2 and the third planarization sub-layer PLN3 are all in direct contact with a surface of the intermediate structure layer 2 away from the base substrate 1. A first surface S1 of the planarization layer PLN is a surface of the third planarization sub-layer PLN3 away from the second planarization sub-layer PLN2.

For example, an orthographic projection of the third planarization sub-layer PLN3 on the base substrate 1 completely covers an orthographic projection of the second planarization sub-layer PLN2 on the base substrate 1. The orthographic projection of the second planarization sub-layer PLN2 on the base substrate 1 completely covers an orthographic projection of the first planarization sub-layer PLN1 on the base substrate 1.

In this embodiment, the planarization layer PLN includes three sequentially disposed layers, that is, the first planarization sub-layer PLN1, the second planarization sub-layer PLN2, and the third planarization sub-layer PLN3, which sequentially wraps the boundary portions of the layers close to the first isolation pillar 3, thereby advantageously protecting the underneath intermediate structure layer 2, and improving the flatness, so as to easily form the light-emitting layer EL.

It should be noted that the planarization layer PLN in the present disclosure includes, but is not limited to, the first planarization sub-layer PLN1, the second planarization sub-layer PLN2, and the third planarization sub-layer PLN3, which are stacked. Alternatively, the planarization layer PLN may be one or a combination of the first planarization sub-layer PLN1, the second planarization sub-layer PLN2, and the third planarization sub-layer PLN3. In the embodiments of the present disclosure, as an example, the planarization layer PLN includes the first planarization sub-layer PLN1, the second planarization sub-layer PLN2, and the third planarization sub-layer PLN3.

For example, materials of the first planarization sub-layer PLN1, the second planarization sub-layer PLN2, and the third planarization sub-layer PLN3 may be an organic material. An organic layer is thicker than an inorganic layer such as a passivation layer PVX, thereby easily realizing the planarization.

In some embodiments, a thickness and/or a size of the planarization layer PLN is adjusted in consideration of the influence of the actual structure of the product, such as a range of the thickness and the size of the planarization layer PLN, and finally a is determined to be in a range from 30° to 40°. In the structure of the three planarization sub-layers PLN shown in FIG. 4, a dihedral angle α formed between a tangent plane at any point on the first surface S1 of the third planarization sub-layer PLN3 in the inclined region EE and the second surface is between 30° and 40°. In this regard, the width of the first groove 5 meets W=α×k∈[14.4 um, 26 um].

For example, shown in FIG. 4, with a greater a, a smaller value of k may be selected, such as k=0.48, and the width W1 of the first groove 5 is set in a rang from 14.4 um to 19.2 um.

For example, a sum of thicknesses of the first planarization sub-layer PLN1, the second planarization sub-layer PLN2 and the third planarization sub-layer PLN3 is between 5 um and 6 um.

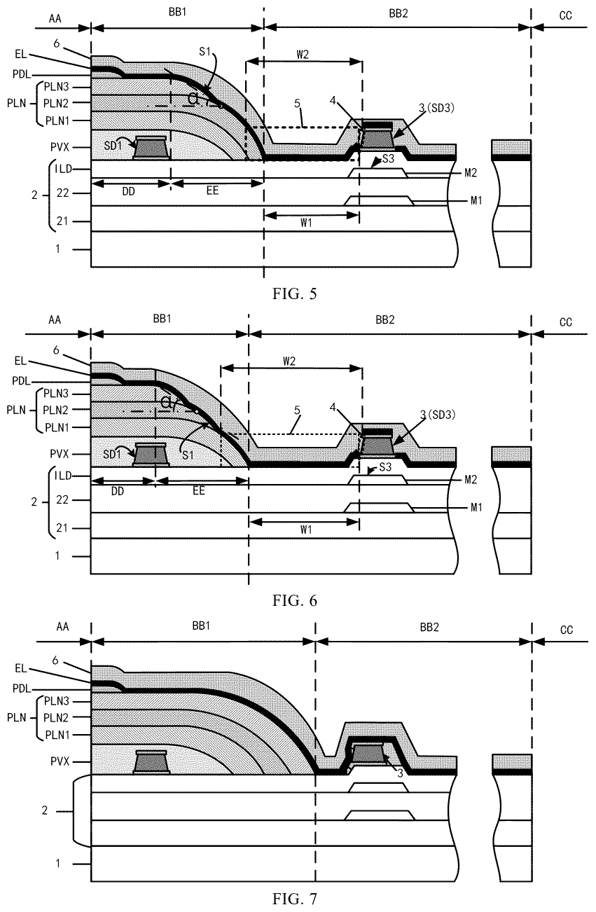

In some embodiments, FIG. 5shows another structure with the optimized first groove, in particular, the planarization layer PLN includes a first planarization sub-layer PLN1, a second planarization sub-layer PLN2, and a third planarization sub-layer PLN3, which are sequentially arranged in a direction away from the base substrate 1. Optionally, the second planarization sub-layer PLN2 wraps at least a boundary portion of the first planarization sub-layer PLN1 close to the first isolation pillar 3, for example, the second planarization sub-layer PLN2 wraps at least a surface of the first planarization sub-layer PLN1 in the inclined region EE; the third planarization sub-layer PLN3 covers a part of the surface of the second planarization sub-layer PLN2 located in the inclined region EE. A part, located in the inclined region EE and not covered by the third planarization sub-layer PLN3, of the surface of the second planarization sub-layer PLN2 away from the base substrate 1 is continuous with a part of the surface of the third planarization sub-layer PLN3 located in the inclined region EE to form the first surface S1 together with the surface of the third planarization sub-layer PLN3 located in the flat region DD.

A difference between the third planarization sub-layer PLN3 shown in FIG. 5 and the third planarization sub-layer PLN3 shown in FIG. 4 is that a boundary of the third planarization sub-layer PLN3 shown in FIG. 5 is farther away from the second transition region BB2, that is, the boundary of the third planarization sub-layer PLN3 is retracted onto the surface of the second planarization sub-layer PLN2 away from the first planarization sub-layer PLN1, compared with the structure shown in FIG. 4, the opening width W2 of the first groove 5 is wider, and the boundary retraction of the third planarization sub-layer PLN3 further increases the width W1 of the first groove 5, which is beneficial to clean out the residual glue 01 in the first groove 5, and ensures that the first isolation pillar 3 can completely cut off the light-emitting layer EL, thereby blocking the water oxygen invading path, and avoiding the defects such as GDS.

For example, the orthographic projection of the second planarization sub-layer PLN2 on the base substrate 1 completely covers the orthographic projection of the first planarization sub-layer PLN1 on the base substrate 1. The orthographic projection of the third planarization sub-layer PLN3 on the base substrate 1 partially covers the orthographic projection of the second planarization sub-layer PLN2 on the base substrate 1.

In some embodiments, as shown in FIG. 5, an outline edge of the orthographic projection of the third planarization sub-layer PLN3 on the base substrate 1 is further away from the second transition region BB2 than an outline edge of the orthographic projection of the first planarization sub-layer PLN1 on the base substrate 1, ensuring an increase in the opening width W2 of the first groove 5. The opening width W2 of the first groove 5 may be understood as: a shortest distance from an edge of a surface, of the first isolation pillar 3 away from the base substrate 1, close to the display region AA horizontally extending to contact with the second planarization sub-layer PLN2.

In some embodiments, as shown in FIG. 5, considering the influence of the actual structure of the product, a is finally determined to be in a range from 22° to 30° by adjusting a retraction distance of the edge and/or a thickness of the third planarization sub-layer PLN3 on the basis of the retraction of the edge of the third planarization sub-layer PLN3. In the structure of the three planarization sub-layers shown in FIG. 5, the first surface S1 of the planarization layer PLN is a surface formed by the surface of the third planarization sub-layer PLN3 that is located in the inclined region EE and in contact with the light-emitting layer EL, together with the surface of the second planarization sub-layer PLN2 that is located in the inclined region EE and in contact with the light-emitting layer EL. A dihedral angle α formed between a tangent plane at any point on the first surface S1 and the second surface is between 22°and 30°. In this regard, the width of the first groove 5 meets W=α×k∈[10.56 um, 19.5 um].

For example, shown in FIG. 5, with a small α, in order to ensure that the width W1 of the first groove 5 is not too narrow, a large value k may be selected, for example, k is selected to be 0.565, so that the width W1 of the first groove 5 is set to be between 11.3 um and 16.95 um.

For example, as shown in FIG. 5, a distance between an orthographic projection of an edge of the third planarization sub-layer PLN3 on the base substrate 1 and an orthographic projection of an edge of the first planarization sub-layer PLN1 on the base substrate 1 is between 5 um and 10 um.

For example, as shown in FIG. 5, the thickness of the third planarization sub-layer PLN3 is between 1.5 um and 2.5 um.

In some embodiments, as shown in FIG. 6, yet another structure with the optimized first groove is shown. Specifically, the planarization layer PLN includes a first planarization sub-layer PLN1, a second planarization sub-layer PLN2, and a third planarization sub-layer PLN3, which are sequentially arranged in a direction away from the base substrate 1. Optionally, the second planarization sub-layer PLN2 covers a part of the surface of the first planarization sub-layer PLN1 located in the inclined region EE; the third planarization sub-layer PLN3 covers a part of the surface of the second planarization sub-layer PLN2 located in the inclined region EE. A part of the surface, located in the inclined region EE and not covered by the second planarization sub-layer PLN2, of the first planarization sub-layer PLN2 away from the base substrate 1 is continuous with a part of the surface of the second planarization sub-layer PLN2 located in the inclined region EE. A part, located in the inclined region EE and not covered by the third planarization sub-layer PLN3, of the surface of the second planarization sub-layer PLN2 away from the base substrate 1 is continuous with a part of the surface of the third planarization sub-layer PLN3 located in the inclined region EE to form the first surface S1 together with the surface of the third planarization sub-layer PLN3 located in the flat region DD.

A difference between the structure shown in FIG. 6 and the structure shown in FIG. 5 is that a boundary of the second planarization sub-layer PLN2 and a boundary of the third planarization sub-layer PLN3 shown in FIG. 6 are farther away from the second transition region BB2, that is, the boundary of the second planarization sub-layer PLN2 is retracted onto the surface of the first planarization sub-layer PLN1 away from the passivation layer PVX. Compared with the structure shown in FIG. 5, the opening width W2 of the first groove 5 is wider, and the boundary retraction of the second planarization sub-layer PLN2 further increases the width W1 of the first groove 5, which is beneficial to clean out the residual glue 01 in the first groove 5, and ensures that the first isolation pillar 3 can completely cut off the light-emitting layer EL, thereby blocking the water oxygen invading path, and avoiding the defects such as GDS.

For example, the orthographic projection of the second planarization sub-layer PLN2 on the base substrate 1 partially covers the orthographic projection of the first planarization sub-layer PLN1 on the base substrate 1. The orthographic projection of the third planarization sub-layer PLN3 on the base substrate 1 partially covers the orthographic projection of the second planarization sub-layer PLN2 on the base substrate 1.

In some embodiments, as shown in FIG. 6, considering the influence of the actual structure of the product, a is finally determined to be in a range from 18° to 22° by adjusting retraction distances of the edges and/or thicknesses of the second planarization sub-layer PLN2 and the third planarization sub-layer PLN3 on the basis of the retraction of the edge of the second planarization sub-layer PLN2 and the third planarization sub-layer PLN3. In the structure of the three planarization sub-layers shown in FIG. 6, the first surface S1 of the planarization layer PLN is a surface formed by the surface of the third planarization sub-layer PLN3 that is located in the inclined region EE and in contact with the light-emitting layer EL, the surface of the second planarization sub-layer PLN2 that is located in the inclined region EE and in contact with the light-emitting layer EL, together with the surface of the first planarization sub-layer PLN1 that is located in the inclined region EE and in contact with the light-emitting layer EL. A dihedral angle α formed between a tangent plane at any point on the first surface S1 and the second surface is between 18° and 22°. In this regard, the width of the first groove 5 meets W=α×k∈[8.64 um, 14.3 um].

For example, as shown in FIG. 6, with a small a, in order to ensure that the width W1 of the first groove 5 is not too narrow, a large value k may be selected, for example, k is selected to be 0.65, so that the width W1 of the first groove 5 is set to be between 11.7 um and 14.3 um.

For example, as shown in FIG. 6, a distance between an orthographic projection of an edge of the second planarization sub-layer PLN2 on the base substrate 1 and the orthographic projection of the edge of the first planarization sub-layer PLN1 on the base substrate 1 is between 5 um and 10 um.

For example, as shown in FIG. 6, a distance between the orthographic projection of the edge of the third planarization sub-layer PLN3 on the base substrate 1 and the orthographic projection of the edge of the second planarization sub-layer PLN2 on the base substrate 1 is between 5 um and 10 um.

For example, as shown in FIG. 6, the thickness of the second planarization sub-layer PLN2 is between 1.5 um and 2.5 um. The thickness of the third planarization sub-layer PLN3 is between 1.5 um and 2.5 um. Optionally, the thickness of the second planarization sub-layer PLN2 is 2 um; and the thickness of the third planarization sub-layer PLN3 is 2 um.

For example, as shown in FIG. 6, the thickness of the first planarization sub-layer PLN1 is between 1.5 um and 2.5 um. Optionally, the thickness of the first planarization sub-layer PLN1 is 2.5 um.

In some embodiments, the width W1 of the first groove 5 is between 13 um and 17 um.

In some embodiments, as shown in FIG. 4 to FIG. 6, the display panel 100 further includes a metal line (for example, a first metal line MI and/or a second metal line M2) disposed on a side of the planarization layer PLN close to the base substrate 1, and an orthographic projection of the metal line on the base substrate 1 covers an orthographic projection of the corresponding isolation pillar on the base substrate 1.

In the present embodiment, the isolation pillar is arranged above the metal line (MI and/or M2) to raise the isolation pillar, thereby facilitating cutting off the light-emitting layer EL. Here, the isolation pillar may be the first isolation pillar 3 and/or the second isolation pillar. For ease of understanding, the first isolation pillar 3 is taken as an example in the present disclosure.

For example, the metal line is a part of the intermediate structure layer 2, and may be a gate line, an electrode plate of a capacitor, or a gate electrode of a thin film transistor or the like.

For example, the metal line has a single-layer structure, and the first isolation pillar 3 is a metal isolation pillar with a multi-layer structure.

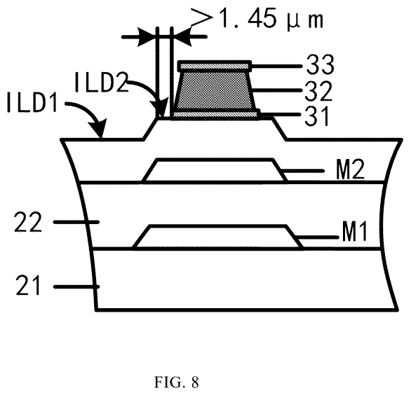

In addition to the risk of the residual glue 01, the structural stability of the first isolation pillar 3 itself is directly related to the encapsulation effect of the product. When a position of the first isolation pillar 3 is shifted due to process fluctuation such that the boundary of the first isolation pillar 3 is not in the flat region DD, the undercut structure 4 will collapse. As shown in FIG. 7, the undercut structure 4 of the first isolation pillar 3 close to the display region AA collapses. Under the circumstances, if the undercut structure 4 of the first isolation pillar 3 close to the opening region cannot cut off the light-emitting layer EL due to external factors (which is a small probability event, but may occur), the encapsulation will fail.

In some embodiments, the display panel 100 further includes an interlayer insulating layer ILD disposed between the isolation pillar and the metal line. As shown in FIGS. 4 to 6, the interlayer insulating layer ILD is disposed between the isolation pillar and the second metal line M2, and includes a flat portion ILDI and a protruding portion ILD2 disposed facing to/opposite to/correspondingly to the second metal line M2. The isolation pillar is arranged on a surface of the protruding portion ILD2 away from the base substrate 1, so that it can be ensured that the isolation pillar is formed on a flat surface while the isolation pillar is raised, the occurrence of the situation that the light-emitting layer EL cannot be cut off due to collapsing of the undercut structure 4 is reduced, and the probability of encapsulation failure is reduced. The isolation pillar herein may be any isolation pillar in the display panel 100, such as the first isolation pillar 3 and/or the second isolation pillar. The first isolation pillar 3 is taken as an example in the present disclosure.

In some embodiments, FIG. 8 is an enlarged view of an isolation pillar according to an embodiment of the present disclosure, specifically, an enlarged view of the first isolation pillar 3 in FIGS. 4 to 6. As shown in FIG. 8, the isolation pillar includes a first conductive portion 31, a second conductive portion 32, and a third conductive portion 33, which are sequentially arranged in the direction away from the base substrate 1; the first conductive portion 31 and the third conductive portion 33 respectively protrude from the second conductive portion 32, that is, a cross section of a combination of the first conductive portion 31, the second conductive portion 32 and the third conductive portion 33 has an “I” shape, so as to form the undercut structure 4 for cutting off the light-emitting layer EL.

In some embodiments, as shown in FIG. 8, a difference between a width of the protruding portion ILD 2 and a width of the first conductive portion 31 is greater than 2.9 um. In the embodiment, the width of the first conductive portion 31 is reduced, so that the difference between the width of the protruding portion ILD2 and the width of the first conductive portion 31 is greater than 2.9 um, thereby ensuring that the isolation pillar is still located on the flat surface where the protruding portion ILD2 is located under the fluctuation of the fabrication process, and avoiding the collapse.

For example, as shown in FIG. 8, a shortest distance from an edge of the protruding portion ILD 2 to an edge of the first conductive portion 31 is greater than 1.45 um.

In some embodiments, as shown in FIG. 8, a ratio of the width of the first conductive portion 31 to a width of the metal line is between 0.4 and 0.6.

For example, the metal line includes a first metal line M1 and a second metal line M2, and the second metal line M2 is closer to the first isolation pillar 3 than the first metal line M1. For example, the second metal line M2 is disposed facing to/opposite to/corresponding to the first isolation pillar 3. A ratio of the width of the first conductive portion 31 to a width of the second metal line M2 is between 0.4 and 0.6. The width of the second metal line M2 may be understood as a width of a surface of the second metal line M2 away from the base substrate, or an average width of two surfaces of the second metal line M2 opposite to each other in a thickness direction of the second metal line M2. For another example, the first metal line M1 is disposed facing to/opposite to/corresponding to the first isolation pillar 3. A ratio of the width of the first conductive portion 31 to a width of the first metal line M2 is between 0.4 and 0.6. The width of the first metal line M1 can be understood as a width of a surface of the first metal line M1 away from the base substrate, or an average width of two surfaces of the first metal line M1 opposite to each other in a thickness direction of the first metal line M1.

The ratio of the width of the first conductive portion 31 to the width of the metal line is set to be between 0.4 and 0.6 in this embodiment, so as to ensure that the isolation pillar still locates on the flat surface in the case of process fluctuation.

In some embodiments, the first conductive portion 31 has a width between 3.8 um to 4.2 um. A third surface S3 of the second metal line M2 away from the base substrate has a width between 0.76 um and 0.84 um.

In some embodiments, as shown in FIGS. 4 to 6, the display panel includes a first insulating layer 21, a first gate line (not shown, which may be understood as a gate line of the thin film transistor located in the display region), a second insulating layer 22, a second gate line (not shown, which may be understood as a gate line of the thin film transistor located in the display region AA), an interlayer insulating layer ILD, a first signal line SD1 (located in the first transition region BB1, which may be a signal line of a sensor located in the opening), the first planarization sub-layer PLN1, a second signal line (not shown, which may be a source/drain electrode line of the thin film transistor located in the display region AA), the second planarization sub-layer PLN2, a third signal line SD3 (located in the second transition region BB2), and the third planarization sub-layer PLN3, which are sequentially disposed in the direction away from the base substrate 1. The metal line includes the first metal line M1 and the second metal line M2; the first metal line M1 and the first gate line are arranged in the same layer, and the second metal line M2 and the second gate line are arranged in the same layer; the first isolation pillar 3 is disposed in the same layer as one of the first signal line SD1, the second signal line and the third signal line SD3.

For example, the first isolation pillar 3 is disposed in the same layer as the third signal line SD3.

For example, as shown in FIGS. 4 to 6, the third signal line SD3 is also used as/serves as the first isolation pillar 3.

In some embodiments, as shown in FIGS. 4 to 6, the first isolation pillar 3 is disposed facing to the second metal line M2, the second metal line M2 includes a third surface S3 away from the base substrate, and a difference between a width of the third surface S3 and the width of the first conductive portion 31 is greater than 2.9 um. In the embodiment, the width of the second metal line M2 is increased or the width of the first conductive portion 31 is reduced, so that the difference between the width of the second metal line M2 and the width of the first conductive portion 31 is greater than 2.9 um, and thus it is ensured that the isolation pillar is still located on the flat surface where the protruding portion ILD2 is located under the fluctuation of the fabrication process, and thus collapse is avoided.

In some embodiments, as shown in FIGS. 4 to 6, the display panel 100 further includes an encapsulation layer 6 disposed on a side of the light-emitting layer EL away from the planarization layer PLN for encapsulating the light-emitting devices, so that deterioration of the light-emitting devices caused by moisture and/or oxygen in the environment may be reduced or prevented. The encapsulation layer 6 may have a single-layer structure or a multi-layer structure including an inorganic layer and an organic layer stacked on each other. For example, the encapsulation layer 6 includes a first inorganic encapsulation layer, an organic encapsulation layer, and a second inorganic encapsulation layer, which are sequentially disposed in the direction away from the base substrate 1. The encapsulation layer 6 extends from the display region AA to the second transition region BB2, so as to cover the isolation pillar.

For example, a material of the encapsulation layer 6 may include silicon oxynitride (SiON), silicon oxide (SiOx), silicon nitride (SiNx), polymer resin, or other insulating materials. Inorganic materials such as silicon oxynitride (SiON), silicon oxide (SiOx), and silicon nitride (SiNx) have high compactness and thus can prevent invading of water, oxygen, and the like; a material of the organic encapsulation layer may be a polymer material containing a desiccant, a polymer material capable of blocking moisture, or the like, such as a polymer resin, to planarize the surface of the display panel 100, and relieve stress of the first inorganic encapsulation layer and the second inorganic encapsulation layer. The material of the organic encapsulation layer may further include a water-absorbing material such as a desiccant to absorb water, oxygen, and other substances invading inside the display panel 100.

In some embodiments, as shown in FIG. 4 to FIG. 6, the display panel further includes the passivation layer PVX disposed on a side of the planarization layer PLN close to the base substrate 1, and a signal line disposed on a side of the passivation layer PVX close to the base substrate 1; the passivation layer PVX wraps a third metal line M3, and the planarization layer PLN wraps the passivation layer PVX. Here, the third metal line M3 may have a multi-layer metal structure, such as a titanium aluminum titanium (Ti/Al/Ti) structure. The third metal line M3 is, for example, a source electrode or a drain electrode of the thin film transistor, or the signal line of the device in the opening region, or the like.

In some embodiments, the display panel 100 further includes a touch functional layer disposed on the encapsulation layer 6, and the touch functional layer includes a touch buffer layer, a first touch metal layer (TMA), a touch insulating layer (TLD), a second touch metal layer (TMB), and a touch protective layer (TOC) sequentially disposed in the direction away from the base substrate 1. An edge of the display region AA close to the second transition region BB2 is not provided with the first touch metal layer and the second touch metal layer but is provided with the touch insulating layer. The touch insulating layer and the touch protective layer extend from the display region AA to the second transition region BB2.

In some embodiments, the display panel 100 is an OLED display panel 100.

In addition, the embodiment of the present disclosure further provides a display apparatus, which includes the display panel in any one of the above embodiments. The display apparatus may be any product with a display function, such as a mobile phone, a tablet computer, a television, a display, a notebook computer, a digital photo frame, or a vehicle-mounted device or the like. Other essential components of the display apparatus are understood by one of ordinary skill in the art, and are not described herein nor should they be construed as limiting the present disclosure.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and essence of the present disclosure, and such changes and modifications also fall within the scope of the present disclosure.

In the claims:

1. A display panel, comprising a display region, a first transition region, a second transition region, and an opening region, wherein the second transition region surrounds the opening region and is located between the first transition region and the opening region, the first transition region surrounds the second transition region and is located between the display region and the first transition region, the display panel comprises a base substrate, a planarization layer on the base substrate, a light-emitting layer on a side of the planarization layer away from the base substrate, and at least one isolation pillar on the base substrate, the planarization layer extends from the display region to the first transition region, the light-emitting layer extends from the display region to the second transition region and is disconnected at a position of each isolation pillar, and the at least one isolation pillar is located in the second transition region;
an isolation pillar surrounding the opening region and closest to the display region is a first isolation pillar, and a first groove on the base substrate is defined between the first isolation pillar and the planarization layer; and
the planarization layer comprises a flat region and an inclined region, the planarization layer comprises a first surface away from the base substrate, a tangent plane at any point on the first surface in the inclined region and a second surface of the base substrate close to the planarization layer form a dihedral angle α therebetween, and a width of the first groove satisfies a formula: W=α×k, where W denotes the width of the first groove, and k represents a coefficient, k∈[0.48, 0.65].

2. The display panel according to claim 1, wherein the planarization layer comprises a first planarization sub-layer, a second planarization sub-layer, and a third planarization sub-layer sequentially arranged in a direction away from the base substrate; and
the second planarization sub-layer at least wraps a boundary portion of the first planarization sub-layer close to the first isolation pillar, and the third planarization sub-layer at least wraps a boundary portion of the second planarization sub-layer close to the first isolation pillar.

3. The display panel according to claim 2, wherein the dihedral angle a between the tangent plane and the second surface is between 30° and 40°.

4. The display panel according to claim 1, wherein the planarization layer comprises a first planarization sub-layer, a second planarization sub-layer, and a third planarization sub-layer sequentially arranged in a direction away from the base substrate;
the second planarization sub-layer at least wraps a boundary portion of the first planarization sub-layer close to the first isolation pillar, and the third planarization sub-layer covers a part of a surface of the second planarization sub-layer located in the inclined region; and
a part, located in the inclined region and not covered by the third planarization sub-layer, of the surface of the second planarization sub-layer away from the base substrate is continuous with a part of a surface of the third planarization sub-layer located in the inclined region to form the first surface together with the surface of the third planarization sub-layer located in the flat region.

5. The display panel according to claim 4, wherein an outline edge of an orthographic projection of the third planarization sub-layer on the base substrate is farther from the second transition region than an outline edge of an orthographic projection of the first planarization sub-layer on the base substrate.

6. The display panel according to claim 4, wherein the dihedral angle α between the tangent plane and the second surface is between 22° and 30°.

7. The display panel according to claim 1, wherein the planarization layer comprises a first planarization sub-layer, a second planarization sub-layer, and a third planarization sub-layer sequentially arranged in a direction away from the base substrate;
the second planarization sub-layer covers a part of a surface of the first planarization sub-layer located in the inclined region, and the third planarization sub-layer covers a part of a surface of the second planarization sub-layer located in the inclined region; and
a part, located in the inclined region and not covered by the second planarization sub-layer, of the surface of the first planarization sub-layer away from the base substrate is continuous with a part of the surface of the second planarization sub-layer located in the inclined region; and a part, located in the inclined region and not covered by the third planarization sub-layer, of the surface of the second planarization sub-layer away from the base substrate is continuous with a part of the surface of the third planarization sub-layer located in the inclined region to form the first surface together with the surface of the third planarization sub-layer located in the flat region.

8. The display panel according to claim 7, wherein the dihedral angle α between the tangent plane and the second surface is between 18° and 22°.

9. The display panel according to claim 1, wherein the display panel further comprises a metal line on a side of the planarization layer close to the base substrate; and
an orthographic projection of the metal line on the base substrate covers an orthographic projection of the corresponding isolation pillar on the base substrate.

10. The display panel according to claim 9, wherein the display panel further comprises an interlayer insulating layer located between the at least one isolation pillar and the metal line, and the interlayer insulating layer comprises a flat portion and a protruding portion opposite to the metal line; and
the at least one isolation pillar is located on a surface of the protruding portion away from the base substrate.

11. The display panel according to claim 9, wherein each isolation pillar comprises a first conductive portion, a second conductive portion, and a third conductive portion sequentially arranged in a direction away from the base substrate; and the first conductive portion and the third conductive portion both protrude from the second conductive portion.

12. The display panel according to claim 11, wherein a difference between a width of the protruding portion and a width of the first conductive portion is greater than 2.9 um.

13. The display panel according to claim 11, wherein a ratio of a width of the first conductive portion to a width of the metal line is between 0.4 and 0.6.

14. The display panel according to claim 11, wherein the display panel comprises a first insulating layer, a first gate line, a second insulating layer, a second gate line, an interlayer insulating layer, a first signal line, a first planarization sub-layer, a second signal line, a second planarization sub-layer, a third signal line, and a third planarization sub-layer sequentially arranged in the direction away from the base substrate;
the metal line comprises a first metal line arranged in the same layer as the first gate line and a second metal line arranged in the same layer as the second gate line; and
the first isolation pillar is located in the same layer as one of the first signal line, the second signal line and the third signal line.

15. The display panel according to claim 14, wherein the second metal line comprises a third surface away from the base substrate, and a difference between a width of the third surface and a width of the first conductive portion is greater than 2.9 um.

16. A display apparatus, comprising the display panel according to claim 1.

17. The display panel according to claim 5, wherein the dihedral angle a between the tangent plane and the second surface is between 22° and 30°.

18. The display panel according to claim 10, wherein each isolation pillar comprises a first conductive portion, a second conductive portion, and a third conductive portion sequentially arranged in a direction away from the base substrate; and the first conductive portion and the third conductive portion both protrude from the second conductive portion.
